(19) United States
(12) Patent Application Publication
(10) Pub. No.: US 2024/0154421 A1
(43) Pub. Date: May 9, 2024

(54) PORTABLE POWER SYSTEM AND USE THEREOF

(71) Applicant: Hybrid Power Solutions, Etobicoke (CA)

(72) Inventors: Francois Renaud-Byrne, Etobicoke (CA); Michael Pinosa, Mississauga (CA); Xiongyi Cui, Etobicoke (CA)

(21) Appl. No.: 18/504,695

(22) Filed: Nov. 8, 2023

Related U.S. Application Data
(60) Provisional application No. 63/423,579, filed on Nov. 8, 2022.

(51) Int. Cl. H02J 3/32; H01M 10/42; H01M 10/46; H01M 50/383; H02J 3/00; H02J 3/38; H02J 7/00; H05K 7/20

(52) U.S. Cl. CPC H02J 3/32; H01M 10/425; H01M 10/46; H01M 50/383; H02J 3/007; H02J 3/38; H02J 7/0047; H02J 7/00712; H02J 7/007194; H05K 7/20909; H05K 7/20945; H01M 2010/4271; H02J 2207/20; H02J 2300/26

(57) ABSTRACT

A portable power system, including: at least one battery comprising a first plurality of battery cells; a direct current (DC) to alternating current (AC) inverter; at least two battery chargers; an AC input; a plurality of AC outputs; a plurality of sensors; a heating pad; at least one foam pad; at least one fan; a main control printed circuit board (PCB); a battery management system (BMS); and at least a first clamp enclosure housing at least a first set of components of the system.

### CROSS REFERENCE TO RELATED APPLICATIONS

This application claims the benefit of U.S. Provisional Patent Application No. 63/423,579, filed Nov. 8, 2022, which is hereby incorporated herein by reference.

### FIELD OF THE DISCLOSURE

The disclosure generally relates to batteries, and in particular, to an intelligent multi-battery portable power system and a method of operation thereof.

### BACKGROUND

Portable power systems have become increasingly essential for modern living, powering electronic devices, electric vehicles, electric industrial tools, and renewable energy applications. A key challenge in portable power systems is to maximize energy efficiency, ensure long battery life, enhance user convenience, and maximize power output. Current systems often lack efficient control and monitoring mechanisms for external charging and discharging, limiting their versatility and usability. Battery packs combine a number of battery cells, either in parallel, series, or a combination of both, to deliver a desired voltage, capacity, and/or power density. Rechargeable battery packs typically include a battery management system (BMS) that manages their recharging and operation, such as by protecting the battery pack from operating outside its safe operating conditions, monitoring the state of the battery pack, calculating secondary data, reporting the secondary data, etc. The BMS uses various sensors to monitor the state of the battery, including a temperature sensor that is used by a battery charger to detect the end of charging.

While a rechargeable battery pack and BMS are known in the art, further improvement of energy efficiency, longevity, user convenience and control, portability, and power remains for these types of systems.

### SUMMARY

The following presents a simplified summary of some embodiments of the invention in order to provide a basic understanding of the invention. This summary is not an extensive overview of the invention. It is not intended to identify key/critical elements of the invention or to delineate the scope of the invention. Its sole purpose is to present some embodiments of the invention in a simplified form as a prelude to the more detailed description that is presented below.

A portable power system, including: at least one battery including a first plurality of battery cells; a direct current (DC) to alternating current (AC) inverter; at least two battery chargers; an AC input; a plurality of AC outputs; a plurality of sensors; a heating pad; at least one foam pad; at least one fan; a main control printed circuit board (PCB); a battery management system (BMS); and at least a first clamp enclosure housing at least a first set of components of the system.

In some aspects, the system further includes: a second clamp enclosure housing at least a second set of components of the system; a heating pad positioned between the first clamp enclosure and the second clamp enclosure; heat conducting and electrically insulating foam pads positioned between the first clamp enclosure and the heating pad, and the second clamp enclosure and the heating pad; and electrically insulating and flame-retardant foam pads positioned in between each of the first plurality of battery cells.

In some aspects, the BMS is configured to monitor various characteristics of the at least one battery based on sensor data captured by the plurality of sensors; the characteristics of the at least one battery include at least a voltage, a capacity, a health, a temperature, an internal resistance, and a state of charge; and the health is determined based on at least the capacity and the internal resistance.

In some aspects, a load is connected to an AC output of the plurality of AC outputs; the BMS is configured to autonomously control which battery chargers are on and off and when a load is connected and disconnected based on at least some of the characteristics of the battery; the BMS is configured to actuate the at least one battery to output energy by closing a contactor when at least temperature and voltage are within safe ranges and upon confirming at least a temperature sensor and a current sensor of the plurality of sensors are outputting sensor readings prior to closing the contactor; the BMS is configured to disconnect the at least one battery from the inverter, the at least two chargers, and the load when at least one of the temperature and the voltage are outside the safe ranges; and the BMS is configured to actuate the at least battery to stop discharging by opening the contactor when the state of charge of the at least one battery falls below a predetermined state of charge.

In some aspects, the BMS is configured to monitor power into and out of the at least one battery based on sensor data captured by a current sensor the plurality of sensors; the BMS is configured to actuate the at least two battery chargers and the inverter to reduce the power into or out of the at least one battery when the power into or out of the at least one battery exceeds a predetermined threshold; and the BMS is configured to actuate the at least one battery to disconnect by controlling various relays and contactors when the power into or out of the at least one battery is not reduced.

In some aspects, the BMS is configured to monitor a temperature of the at least one battery based on sensor data captured by a temperature sensor of the system; and the BMS communicates at least a status of the at least one battery and current limits of the at least one battery to the at least two battery chargers and the inverters in real-time as the current limits of the at least one battery change based on the temperature of the at least one battery, wherein a maximum current output of the at least one battery decreases as the temperature of the at least one battery increases.

In some aspects, the BMS communicates with the at least two battery chargers and the inverter via CANBUS.

In some aspects, the BMS is configured to monitor a temperature of the at least one battery based on sensor data captured by a temperature sensor of the system; the BMS is configured to actuate the heating pad to activate when the temperature of the at least one battery falls below a first predetermined temperature and until the at least one battery reaches a second predetermined temperature; the BMS is configured to prevent the at least one battery from charging when the temperature of the at least one battery is below the second predetermined temperature; and the BMS is configured to actuate the at least one fan to activate when the temperature of the at least one battery exceeds a third predetermined temperature and until the at least one battery reaches a fourth predetermined temperature.

In some aspects, the inverter is configured to operate off the at least one battery, wherein DC voltage is converted to AC voltage for external loads; and the inverter is configured to operate off at least one external solar panel, wherein the DC voltage is converted to AC voltage for the external loads.

In some aspects, the inverter includes a bypass feature; and the bypass feature prevents the inverter from using energy of the at least one battery when an AC source is available as an output for an external load.

In some aspects, the system further includes an interactive display screen; the interactive display screen is configured to display at least characteristics of the battery, a status of the battery, and current limits of the battery.

In some aspects, the system further includes: a DC input and an external solar panel; the at least two battery chargers operate at a same time or independently; a first battery charger of the at least two battery chargers includes a rectifier that converts an AC power source to a DC output for charging the at least one battery; a second battery charger of the at least two battery chargers includes a solar charger that uses DC power from the external solar panel to charge the at least one battery; and an external charger charges the at least one battery via the DC input.

In some aspects, the system further includes at least one solid-state switch to control the charging and discharging of the at least one battery.

In some aspects, the system is configured to operate in parallel with two other portable power systems; and the system and the two other portable power systems operate in a three-phase parallel configuration using at least a communication line between them and accessory harnesses.

In some aspects, the system is configured to receive battery cells with different cell chemistries including at least: lead acid, lithium-ion, ternary lithium, and solid-state battery chemistries.

In some aspects, the system further includes: integrated solar panels, a sensor for tracking a direction from which maximum sunlight is captured; and a means for adjusting an orientation of the portable power system or the integrated solar panels such that maximum solar energy is captured by the integrated solar panels; and the means for adjusting the orientation of the portable power system or the integrated solar panels autonomously adjusts the orientation of the portable power system or the integrated solar panels based on sensor data of the sensor such that maximum solar energy is captured by the integrated solar panels.

In some aspects, the system is wirelessly connected with an application executed on a mobile computing device; the application is configured to receive user inputs via a user interface of the application instructing the portable power system to autonomously turn on and turn off; the application is configured to receive user inputs via the user interface of the application defining: an operational schedule of the portable power system including days and times the portable power system is to autonomously operate and customized settings of the portable power system; and the user interface of the application is configured to display: a status of the at least one battery, a battery charge level of the at least one battery, at least one sensor reading output, a health of the at least one battery or components of the portable power system, a location of the portable power system, firmware information, maintenance information, historical usage data, and errors with the portable power system.

In some aspects, the system further includes: a clamshell enclosure housing the first clamp enclosure and including at least two wheel housings; a set of wheels coupled to the clamshell enclosure, each wheel of the set of wheels being at least partially housed in one of the at least two wheel housings; and at least one mechanism for detaching and attaching each wheel from and to the clamshell enclosure, respectively, wherein the at least two wheel housings are configured such that wheels with a diameter ranging between at least 5-30 centimeters are attachable to the clamshell enclosure without requiring any modification to the clamshell enclosure.

In some aspects, the system further includes built-in lighting; and a brightness and a direction of the lighting is adjusted using a user interface of the system or using an application wirelessly connected with the system. In some aspects, the system further includes a sensor for detecting a brightness of an environment; and the lighting automatically turns on upon detecting a brightness below a particular brightness threshold; and the lighting brightness automatically adjusts based on the sensed brightness of the environment.

### BRIEF DESCRIPTION OF THE DRAWINGS

For a better understanding of the various embodiments described herein and to show more clearly how they may be carried into effect, reference will now be made, by way of example only, to the accompanying drawings.

FIGS. 1A-1B illustrate an example of a portable power system and components, according to some embodiments.

FIG. 2 illustrates an example of an exploded view of the portable power system battery modules and components, according to some embodiments.

FIG. 3 illustrates an example diagram of connections between components within the portable power system, according to some embodiments.

FIG. 4 illustrates an example of an operational flow chart of a portable power system, according to some embodiments.

### DETAILED DESCRIPTION OF SOME EMBODIMENTS

For simplicity and clarity of illustration, where considered appropriate, reference numerals may be repeated among the Figures to indicate corresponding or analogous elements. In addition, numerous specific details are set forth to provide a thorough understanding of the embodiments described herein. However, it will be understood by those of ordinary skill in the art that the embodiments described herein may be practiced without these specific details. In other instances, well-known methods, procedures, and components have not been described in detail so as not to obscure the embodiments described herein. Also, the description is not to be considered as limiting the scope of the embodiments described herein.

Various terms used throughout the present description may be read and understood as follows, unless the context indicates otherwise: “or” as used throughout is inclusive, as though written “and/or”; singular articles and pronouns as used throughout include their plural forms, and vice versa; “exemplary” should be understood as “illustrative” or “exemplifying” and not necessarily as “preferred” over other embodiments. Further definitions for terms may be set out herein; these may apply to prior and subsequent instances of those terms, as will be understood from a reading of the present description.

Aspects of the invention include a portable power system including at least a battery (i.e., a plurality of battery cells), a direct current (DC) to alternating current (AC) converter or inverter, one or more battery chargers including an AC to DC converter for charging from the grid, a maximum power point tracking (MPPT) solar charger for charging from solar panels, a DC input for charging the battery using an external charger, an AC input, multiple AC outputs, a plurality of sensors, a heating pad, one or more foam pads, one or more fans, a main control printed circuit board (PCB), a battery management system (BMS) for controlling all functions of the system, and a clamp-like enclosure for securing the components of the portable power system. The plurality of sensors includes at least temperature sensors for monitoring battery temperature and current sensors for measuring current leaving or entering the battery.

The portable power system is assembled by stacking battery cells and securing the battery cells and other components of the system within the clamp-like enclosure. The clamp enclosure is modular. For example, two clamp enclosures may be assembled back-to-back. The heating pad is positioned between the clamp enclosures to regulate the temperature of the battery in cold weather conditions. The battery and the heating pad are separated by a heat conducting and electrically insulating foam pad while battery cells are separated from one other by electrically insulating and flame retardant foam pads. Uniquely designed clamps may be added to the clamp enclosure to secure the components within the enclosure.

In operation, the BMS collects and monitors various characteristics of the battery using sensors disposed on the portable power system. Characteristics of the battery include, but are not limited to, voltage, capacity, health, temperature, internal resistance, state of charge, etc. Health may be determined based on at least an observed capacity versus a nominal capacity and internal resistance. The BMS determines what is operational on the main control PCB based on the characteristics of the battery in order to keep the battery operating within safe operational parameters (i.e., temperature, voltage, etc.). These operational parameters are typically predetermined by the battery manufacturer and are programmed on the BMS. The BMS controls which chargers are on and off and when a load is connected to the battery. If the power into or out of the battery exceeds a predetermined threshold, the BMS communicates with both the chargers and inverter to reduce the power into or out of the battery. If the power is not reduced, the BMS controls various relays and contactors to disconnect the battery. This may happen when, for example, the battery is in a low or high state of charge and the power in/out needs to be reduced or in the case of a rogue charger/load. When the temperature of the battery falls below a predetermined temperature, the BMS actuates a heater to activate and warms the battery. When the temperature of the battery exceeds a predetermined threshold, the BMS actuates one or more fans to activate and cool the battery.

The main output of the battery is controlled via a contactor. The contactor is turned on using a button, upon which power is supplied to the DC/DC converter. When all operational parameters are within the safety limits (i.e., temperature, voltage, no short, etc.) set on the BMS and upon confirming a temperature sensor and a Hall-effect current sensor are outputting sensor readings, the BMS closes the contactor, allowing the battery to output. When an issue arises at any point during operation, the BMS opens the contactor, disconnecting the battery from the inverter, charger, and accessory components. When the state of charge of the battery falls below a predetermined threshold, the battery opens the contactor to stop discharging the battery. When the battery is warm, but not exceeding a safe temperature, a set of cooling fans activate and provide cool air to the battery such that it may operate at a more efficient temperature. When the battery is cold and requires charging, an internal heating pad energizes and operates using an external AC source to heat up the battery until the battery reaches a safe temperature for charging, upon which the BMS allows the battery to charge. Temperature thresholds used in determining when to turn fans on and off and disconnect the battery are typically dependent on manufacturer. For instance, when charging the battery, the battery temperature must be above zero degrees Celsius.

The inverter of the portable power system can operate off multiple power sources. The inverter can operate off the battery, wherein the DC voltage is converted to AC voltage and output to external loads. The inverter can also operate off one or more external solar panels, wherein the DC voltage is converted to AC voltage for external loads. The inverter includes a bypass feature, wherein the inverter uses an AC source as the output for external loads when available to refrain from using the energy of the battery. In some embodiments, the portable power system includes two chargers that may operate at the same time or independently. A first charger includes a rectifier that converts an AC power source to a DC output to charge the battery. A second charger includes a solar charger that uses DC power from the external solar panels to charge the battery. An external charger may be used to charge the battery via the DC input. The external charger is required to provide a DC source for the battery to charge. The BMS communicates information to the chargers and/or inverters via CANBUS, wherein status of the battery and current limits of the battery are communicated in real-time. The BMS communicates information to the chargers and/or inverters to provide safety thresholds for the various power converters. For example, current limits change based on the temperature of the battery, wherein a maximum current output of the battery decreases as the battery temperature increases. This communication adds redundancy to ensure monitored characteristics of the battery and converters correspond to one another.

Characteristics of the battery, status of the battery, current limits of the battery and/or other useful information is displayed on an interactive screen mounted on the portable power system and is remotely accessible by an operator using a mobile application. With wireless communication between the BMS and the mobile application, the operator uses the mobile application to remotely control the BMS and inverter such that settings of the portable power system are updated remotely. In some embodiments, the user monitors and controls the portable power system remotely using the mobile application by providing user inputs to the mobile application using a user interface of the application displayed on a mobile phone (or other mobile computing device) executing the mobile application. The mobile application and the portable power system may communicate using radio signals, such as Wi-Fi or Bluetooth. The mobile application may receive user inputs instructing the portable power system to autonomously: immediately turn on or off, turn on or off at a particular day and/or time, and turn on or off upon a timer ending. The mobile application may receive user inputs defining an operational schedule of the portable power system including days and times the portable power system is to autonomously operate and customized settings of the portable power system. The mobile application may provide real-time monitoring of the portable power system, wherein the user interface of the application displays: a status of the battery, a battery charge level of the battery, sensor reading outputs, a health of the battery and/or components of the portable power system, a location of the portable power system, firmware information, maintenance information, historical usage data, and errors with the portable power system, etc. The portable power system is configured to operate according to user inputs received by the mobile application.

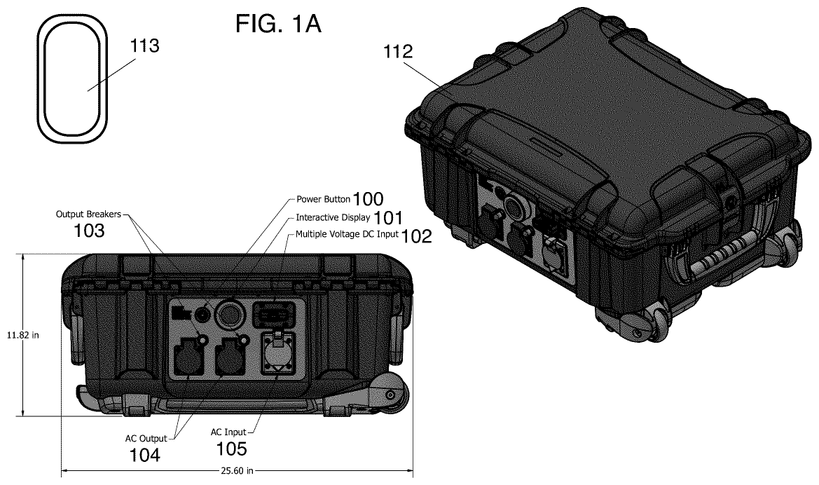

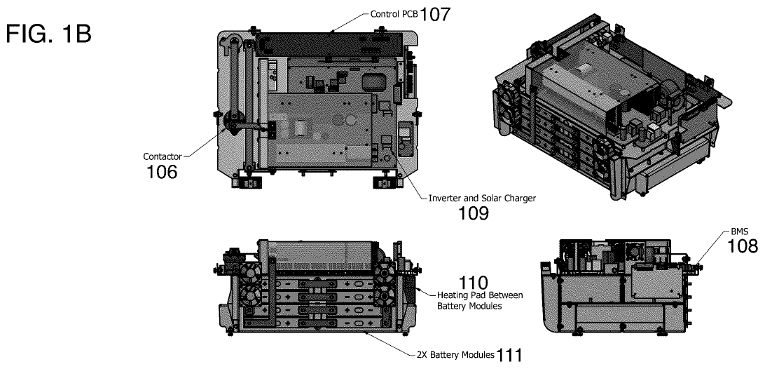

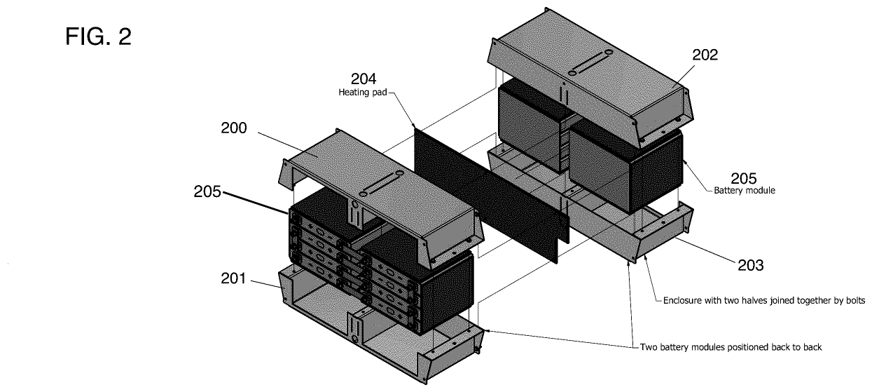

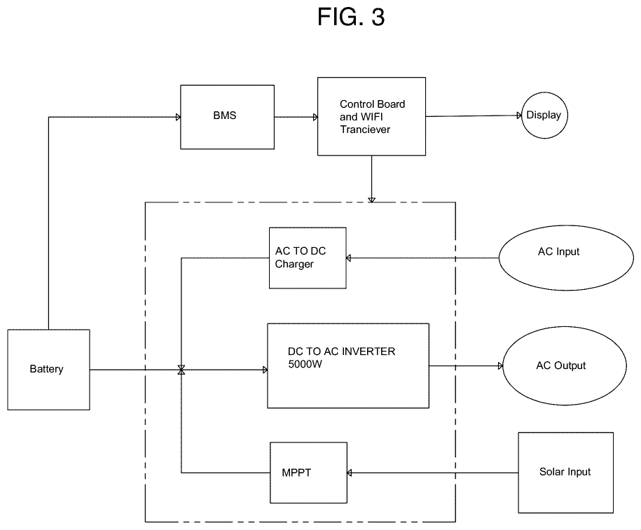

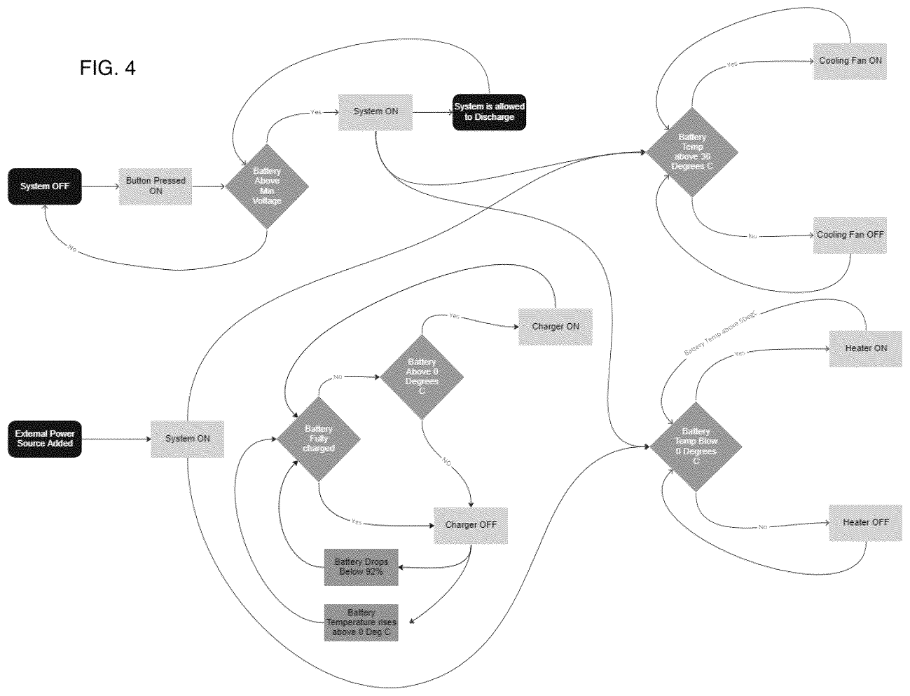

FIGS. 1A and 1B illustrate the portable power system including power button 100, interactive display screen 101, multiple voltage DC inputs 102, output breakers 103, AC output 104, AC input 105, contactor 106, main control PCB 107, BMS 108, inverter and solar charger 109, heating pad 110, battery 111, and clamshell enclosure 112. The smartphone 113 is wirelessly connected to the BMS 108 and communicates with the BMS 108 via the smartphone application. FIG. 2 illustrates an exploded view of the portable power system, wherein clamp enclosures 200 and 201 and 202 and 203 are adjacently joined together using bolts. Joined enclosures 200 and 201 and joined enclosures 202 and 203 are joined back-to-back with a heating pad 204 positioned in between, with battery modules 205 encased in respective clamp enclosures. FIG. 3 illustrates a diagram of connections between some components of the portable power system. FIG. 4 illustrates an operational flow chart of the portable power system, describing conditions for discharging, charging, turning the charger on and off, turning the heater on and off, and turning the fan on and off.

In some embodiments, the portable power system incorporates solid-state switches to control the charging and discharging of energy of the battery, eliminating the need for traditional contactors and relays. This technology enhances efficiency, reduces maintenance, and ensures reliable performance.

In some embodiments, the portable power system is configured to operate in parallel with two other portable power systems. With a communication line and accessory harnesses the three portable power systems may operate in a three-phase parallel configuration, allowing for increased power output and redundancy. This feature is particularly useful for industrial applications and critical infrastructure where power reliability is paramount.

In some embodiments, the portable power system is designed to accommodate swappable and expandable battery modules, offering versatility and scalability. Users can easily increase capacity or replace batteries when necessary, making it adaptable to varying energy demands. In some embodiments, the portable power system is engineered to support various cell chemistries, such as lead acid, lithium-ion, ternary lithium, or solid-state batteries. This versatility allows users to select the most suitable battery type based on their specific requirements or preferences.

In some embodiments, the portable power system is equipped with integrated solar panels featuring sun-tracking technology. This ensures maximum solar energy capture. The portable power system may include a sensor for tracking a direction from which maximum sunlight may be captured and means for adjusting an orientation of the portable power system or the integrated solar panels such that maximum solar energy is captured. The means for adjusting the orientation of the portable power system or the integrated solar panels autonomously adjusts the orientation of the portable power system or the integrated solar panels based on sensor data of the sensor such that maximum solar energy is captured by the integrated solar panels.

In some embodiments, the portable power system features a built-in level two charging station, enabling faster and more efficient charging of electric vehicles or other devices. This capability makes it a valuable asset for electric vehicle charging infrastructure and emergency power applications.

In some embodiments, the portable power system includes a means for integrating with wind turbines to harness wind energy. This feature adds an additional renewable energy source.

The clamshell enclosure may house the battery encased in the clamp enclosure. In some embodiments, the clamshell enclosure of the portable power system includes wheel housings configured to receive different types of wheels for various terrains (e.g., large diameter wheels with large treads for rocky and/or muddy terrain; wide and smooth wheels for sandy terrain; small diameter and smooth wheels for indoor applications), wherein each wheel is at least partially housed within a wheel housing. The wheel housings are configured such that wheels with a particular diameter range (e.g., between at least 5-30 centimeters) and a particular width range are attachable to the clamshell enclosure without requiring any modification to the clamshell enclosure The wheels and wheel housings of the clamshell enclosure are designed such that wheels are easily swappable by the user (e.g., using a mechanism such as a spring-loaded pin to easily detach and attach wheels), making it easy to transport and deploy the portable power system in different environments. The clamshell enclosure and/or the wheels may include the mechanisms for detaching and attaching the wheels from the clamshell enclosure.

In situations where renewable sources are insufficient, the portable power system may include an integrated generator that can run on various fuels (e.g., gasoline, diesel, or natural gas). This backup generator ensures uninterrupted power supply during extended periods of energy scarcity.

In some embodiments, the portable power system includes built-in lighting (e.g., LED floodlights) to provide illumination in dark or emergency situations, enhancing safety and visibility at night. These lights may be adjusted for brightness and direction using a user interface of the portable power system or using the mobile application wirelessly connected with the portable power system. The portable power system may include a sensor for detecting a brightness of the environment and upon detecting a brightness below a particular threshold, the lighting may automatically turn on. The lighting brightness may automatically adjust based on the sensed brightness of the environment. The automatic lighting may be enabled/disabled using the user interface of the portable power system or using the mobile application.

In some embodiments, the portable power system includes a built-in Wi-Fi router. This feature allows users to establish a local network for data sharing, remote monitoring, and communication with other devices. In some embodiments, the portable power system includes wireless charging pads for smartphones and other devices. Users can conveniently charge their devices without the need for cords and adapters.

In some embodiments, the portable power system is equipped with an integrated Heating, Ventilation, and Air Conditioning (HVAC) system for climate control in extreme weather conditions. This ensures a comfortable environment outside the unit, making it suitable for various applications such as mobile offices.

While this invention has been described in terms of several embodiments, there are alterations, permutations, and equivalents, which fall within the scope of this invention. It should also be noted that there are many alternative ways of implementing the methods, devices and apparatuses of the present invention. Furthermore, unless explicitly stated, any method embodiments described herein are not constrained to a particular order or sequence. Further the Abstract is provided herein for convenience and should not be employed to construe or limit the overall invention, which is expressed in the claims. It is therefore intended that the following appended claims to be interpreted as including all such alterations, permutations, and equivalents as fall within the true spirit and scope of the present invention.

In block diagrams, illustrated components are depicted as discrete functional blocks, but embodiments are not limited to systems in which the functionality described herein is organized as illustrated. The functionality provided by each of the components may be provided by specialized software or specially designed hardware modules that are differently organized than is presently depicted; for example, such software or hardware may be intermingled, conjoined, replicated, broken up, distributed (e.g. within a data center or geographically), or otherwise differently organized. The functionality described herein may be provided by one or more processors of one or more computers executing specialized code stored on a tangible, non-transitory, machine readable medium. In some cases, notwithstanding use of the singular term “medium,” the instructions may be distributed on different storage devices associated with different computing devices, for instance, with each computing device having a different subset of the instructions, an implementation consistent with usage of the singular term “medium” herein. In some cases, third party content delivery networks may host some or all of the information conveyed over networks, in which case, to the extent information (e.g., content) is said to be supplied or otherwise provided, the information may be provided by sending instructions to retrieve that information from a content delivery network.

The reader should appreciate that the present application describes several independently useful techniques. Rather than separating those techniques into multiple isolated patent applications, applicants have grouped these techniques into a single document because their related subject matter lends itself to economies in the application process. But the distinct advantages and aspects of such techniques should not be conflated. In some cases, embodiments address all of the deficiencies noted herein, but it should be understood that the techniques are independently useful, and some embodiments address only a subset of such problems or offer other, unmentioned benefits that will be apparent to those of skill in the art reviewing the present disclosure. Due to costs constraints, some techniques disclosed herein may not be presently claimed and may be claimed in later filings, such as continuation applications or by amending the present claims. Similarly, due to space constraints, neither the Abstract nor the Summary of the Invention sections of the present document should be taken as containing a comprehensive listing of all such techniques or all aspects of such techniques.

It should be understood that the description and the drawings are not intended to limit the present techniques to the particular form disclosed, but to the contrary, the intention is to cover all modifications, equivalents, and alternatives falling within the spirit and scope of the present techniques as defined by the appended claims. Further modifications and alternative embodiments of various aspects of the techniques will be apparent to those skilled in the art in view of this description. Accordingly, this description and the drawings are to be construed as illustrative only and are for the purpose of teaching those skilled in the art the general manner of carrying out the present techniques. It is to be understood that the forms of the present techniques shown and described herein are to be taken as examples of embodiments. Elements and materials may be substituted for those illustrated and described herein, parts and processes may be reversed or omitted, and certain features of the present techniques may be utilized independently, all as would be apparent to one skilled in the art after having the benefit of this description of the present techniques. Changes may be made in the elements described herein without departing from the spirit and scope of the present techniques as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an element” or “a element” includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. Limitations as to sequence of recited steps should not be read into the claims unless explicitly specified, e.g., with explicit language like “after performing X, performing Y,” in contrast to statements that might be improperly argued to imply sequence limitations, like “performing X on items, performing Y on the X′ed items,” used for purposes of making claims more readable rather than specifying sequence. Statements referring to “at least Z of A, B, and C,” and the like (e.g., “at least Z of A, B, or C”), refer to at least Z of the listed categories (A, B, and C) and do not require at least Z units in each category. Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device. Features described with reference to geometric constructs, like “parallel,” “perpendicular/orthogonal,” “square”, “cylindrical,” and the like, should be construed as encompassing items that substantially embody the properties of the geometric construct, e.g., reference to “parallel” surfaces encompasses substantially parallel surfaces. The permitted range of deviation from Platonic ideals of these geometric constructs is to be determined with reference to ranges in the specification, and where such ranges are not stated, with reference to industry norms in the field of use, and where such ranges are not defined, with reference to industry norms in the field of manufacturing of the designated feature, and where such ranges are not defined, features substantially embodying a geometric construct should be construed to include those features within 15% of the defining attributes of that geometric construct. The terms “first”, “second”, “third,” “given” and so on, if used in the claims, are used to distinguish or otherwise identify, and not to show a sequential or numerical limitation.

1. A portable power system, comprising:
at least one battery comprising a first plurality of battery cells;
a direct current (DC) to alternating current (AC) inverter;
at least two battery chargers;
an AC input;
a plurality of AC outputs;
a plurality of sensors;
a heating pad;
at least one foam pad;
at least one fan;
a main control printed circuit board (PCB);
a battery management system (BMS); and
at least a first clamp enclosure housing at least a first set of components of the system.

2. The system of claim 1, wherein the system further comprises:
a second clamp enclosure housing at least a second set of components of the system;
a heating pad positioned between the first clamp enclosure and the second clamp enclosure;
heat conducting and electrically insulating foam pads positioned between the first clamp enclosure and the heating pad, and the second clamp enclosure and the heating pad; and
electrically insulating and flame-retardant foam pads positioned in between each of the first plurality of battery cells.

3. The system of claim 1, wherein:
the BMS is configured to monitor various characteristics of the at least one battery based on sensor data captured by the plurality of sensors;
the characteristics of the at least one battery comprise at least a voltage, a capacity, a health, a temperature, an internal resistance, and a state of charge; and
the health is determined based on at least the capacity and the internal resistance.

4. The system of claim 3, wherein:
a load is connected to an AC output of the plurality of AC outputs;
the BMS is configured to autonomously control which battery chargers are on and off and when a load is connected and disconnected based on at least some of the characteristics of the battery;
the BMS is configured to actuate the at least one battery to output energy by closing a contactor when at least temperature and voltage are within safe ranges and upon confirming at least a temperature sensor and a current sensor of the plurality of sensors are outputting sensor readings prior to closing the contactor;
the BMS is configured to disconnect the at least one battery from the inverter, the at least two chargers, and the load when at least one of the temperature and the voltage are outside the safe ranges; and
the BMS is configured to actuate the at least battery to stop discharging by opening the contactor when the state of charge of the at least one battery falls below a predetermined state of charge.

5. The system of claim 1, wherein:
the BMS is configured to monitor power into and out of the at least one battery based on sensor data captured by a current sensor the plurality of sensors;
the BMS is configured to actuate the at least two battery chargers and the inverter to reduce the power into or out of the at least one battery when the power into or out of the at least one battery exceeds a predetermined threshold; and
the BMS is configured to actuate the at least one battery to disconnect by controlling various relays and contactors when the power into or out of the at least one battery is not reduced.

6. The system of claim 1, wherein:
the BMS is configured to monitor a temperature of the at least one battery based on sensor data captured by a temperature sensor of the system; and
the BMS communicates at least a status of the at least one battery and current limits of the at least one battery to the at least two battery chargers and the inverters in real-time as the current limits of the at least one battery change based on the temperature of the at least one battery, wherein a maximum current output of the at least one battery decreases as the temperature of the at least one battery increases.

7. The system of claim 1, wherein:
the BMS communicates with the at least two battery chargers and the inverter via CANBUS.

8. The system of claim 1, wherein:
the BMS is configured to monitor a temperature of the at least one battery based on sensor data captured by a temperature sensor of the system;
the BMS is configured to actuate the heating pad to activate when the temperature of the at least one battery falls below a first predetermined temperature and until the at least one battery reaches a second predetermined temperature;
the BMS is configured to prevent the at least one battery from charging when the temperature of the at least one battery is below the second predetermined temperature; and
the BMS is configured to actuate the at least one fan to activate when the temperature of the at least one battery exceeds a third predetermined temperature and until the at least one battery reaches a fourth predetermined temperature.

9. The system of claim 1, wherein:
the inverter is configured to operate off the at least one battery, wherein DC voltage is converted to AC voltage for external loads; and
the inverter is configured to operate off at least one external solar panel, wherein the DC voltage is converted to AC voltage for the external loads.

10. The system of claim 1, wherein:
the inverter comprises a bypass feature; and
the bypass feature prevents the inverter from using energy of the at least one battery when an AC source is available as an output for an external load.

11. The system of claim 1, wherein:
the system further comprises an interactive display screen;
the interactive display screen is configured to display at least characteristics of the battery, a status of the battery, and current limits of the battery.

12. The system of claim 1, wherein:
the system further comprises:
a DC input; and
an external solar panel;
the at least two battery chargers operate at a same time or independently;
a first battery charger of the at least two battery chargers comprises a rectifier that converts an AC power source to a DC output for charging the at least one battery;
a second battery charger of the at least two battery chargers comprises a solar charger that uses DC power from the external solar panel to charge the at least one battery; and
an external charger charges the at least one battery via the DC input.

13. The system of claim 1, further comprising at least one solid-state switch to control the charging and discharging of the at least one battery.

14. The system of claim 1, wherein:
the system is configured to operate in parallel with two other portable power systems; and
the system and the two other portable power systems operate in a three-phase parallel configuration using at least a communication line between them and accessory harnesses.

15. The system of claim 1, wherein the system is configured to receive battery cells with different cell chemistries comprising at least: lead acid, lithium-ion, ternary lithium, and solid-state battery chemistries.

16. The system of claim 1, wherein:
the system further comprises:
integrated solar panels; and
a sensor for tracking a direction from which maximum sunlight is captured; and
a means for adjusting an orientation of the portable power system or the integrated solar panels such that maximum solar energy is captured by the integrated solar panels; and
the means for adjusting the orientation of the portable power system or the integrated solar panels autonomously adjusts the orientation of the portable power system or the integrated solar panels based on sensor data of the sensor such that maximum solar energy is captured by the integrated solar panels.

17. The system of claim 1, wherein:
the system is wirelessly connected with an application executed on a mobile computing device;
the application is configured to receive user inputs via a user interface of the application instructing the portable power system to autonomously turn on and turn off;
the application is configured to receive user inputs via the user interface of the application defining: an operational schedule of the portable power system including days and times the portable power system is to autonomously operate and customized settings of the portable power system; and
the user interface of the application is configured to display: a status of the at least one battery, a battery charge level of the at least one battery, at least one sensor reading output, a health of the at least one battery or components of the portable power system, a location of the portable power system, firmware information, maintenance information, historical usage data, and errors with the portable power system.

18. The system of claim 1, further comprising:
a clamshell enclosure housing the first clamp enclosure and comprising at least two wheel housings;
a set of wheels coupled to the clamshell enclosure, each wheel of the set of wheels being at least partially housed in one of the at least two wheel housings; and
at least one mechanism for detaching and attaching each wheel from and to the clamshell enclosure, respectively, wherein the at least two wheel housings are configured such that wheels with a diameter ranging between at least 5-30 centimeters are attachable to the clamshell enclosure without requiring any modification to the clamshell enclosure.

19. The system of claim 1, wherein:
the system further comprises built-in lighting; and
a brightness and a direction of the lighting is adjusted using a user interface of the system or using an application wirelessly connected with the system.

20. The system of claim 19, wherein:
the system further comprises a sensor for detecting a brightness of an environment; and
the lighting automatically turns on upon detecting a brightness below a particular brightness threshold; and
the lighting brightness automatically adjusts based on the sensed brightness of the environment.
